(19) United States
(12) Patent Application Publication
(10) Pub. No.: US 2014/0254280 A1
(43) Pub. Date: Sep. 11, 2014

(54) Programming Method For Memory Cell

(71) Applicant: Macronix International Co., Ltd., Hsinchu (TW)

(72) Inventors: Hsing Wen Chang, Toufen Township (TW); Yao Wen Chang, Hsinchu City (TW); Yuan-Peng Chao, Hsinchu City (TW)

(73) Assignee: Macronix International Co., Ltd., Hsinchu (TW)

(21) Appl. No.: 13/900,425

(22) Filed: May 22, 2013

Related U.S. Application Data
(60) Provisional application No. 61/775,743, filed on Mar. 11, 2013.

(51) Int. Cl. G11C 16/12

(52) U.S. Cl. CPC G11C 16/12
USPC 365/185.19; 365/185.18

(57) ABSTRACT

A method for programming memory cells includes applying a programming voltage to a selected memory cell in a memory cell array and a neighboring passing voltage to a neighboring memory cell next to the selected memory cell, increasing the programming voltage for programming the selected memory cell, and increasing the neighboring passing voltage for programming the selected memory cell.

### CROSS-REFERENCE TO RELATED APPLICATIONS

This application is based upon and claims the benefit of priority from Provisional Application No. 61/775,743, filed on Mar. 11, 2013, the entire content of which is incorporated herein by reference.

### TECHNOLOGY FIELD

The disclosure relates to memory cells and, more particularly, to a method for programming memory cells.

### BACKGROUND

Flash memory, such as a NAND type flash memory, is a non-volatile storage device widely used in, e.g., computer memory, memory cards, USB flash drives, and solid-state drives. A flash memory includes an array of memory cells. A memory cell of a flash memory is similar to a normal MOS transistor, except that a flash memory cell has an additional, floating gate formed between, and insulated from, a control gate and a channel. The structure of a MOS transistor with an additional, floating gate can sometimes be referred to as a floating-gate MOS transistor. A flash memory cell may have different threshold voltages when electrical charges are present or absent in the floating gate. For example, when there are no charges in the floating gate, the threshold voltage of the memory cell may be low, indicating one of the two binary values “0” and “1”. When electrical charges are injected into and trapped in the floating gate, the threshold voltage of the memory cell may become higher, indicating the other one of the two binary values.

A flash memory cell may be programmed by an incremental step pulse programming (ISPP) method, in which an electrical pulse is repeatedly applied to a control gate of the memory cell with a voltage of the electrical pulse incrementally increased each time the electrical pulse is applied. In the present disclosure, each time an electrical pulse is applied to a memory cell or electrical pulses are simultaneously applied to different memory cells may be referred to as a shot. This programming process using electrical pulses is schematically shown in FIG. 1(A), in which the abscissa is a shot number (for example, number “5” in the abscissa represents the 5th time an electrical pulse is (or electrical pulses are) applied) and the ordinate is the threshold voltage of the memory cell. The programming process is finished when the threshold voltage of the memory cell becomes equal to or higher than a programming verification voltage V_{PV}. However, because of various factors such as, for example, the approach used for programming and deviation among memory cells, there may be a threshold voltage distribution among programmed memory cells. FIG. 1(B) schematically illustrates a threshold voltage distribution of a memory cell before and after the programming. The after-programming distribution cuts off at V_{PV} since programming ends if the threshold is equal to or larger than V_{PV}. A smaller threshold voltage distribution after programming may be desired.

### SUMMARY

In accordance with the disclosure, there is provided a method for programming memory cells. The method includes applying a programming voltage to a selected memory cell in a memory cell array and a neighboring passing voltage to a neighboring memory cell next to the selected memory cell, increasing the programming voltage for programming the selected memory cell, and increasing the neighboring passing voltage for programming the selected memory cell.

Also in accordance with the disclosure, there is provided a device for programming memory cells. The device includes a programming voltage generator configured to generate a programming voltage to be applied to a selected memory cell in a memory cell array, the programming voltage generator configured to increase the programming voltage for programming the selected memory cell. The device also includes a neighboring passing voltage generator configured to generate a neighboring passing voltage to be applied to a neighboring memory cell next to the selected memory cell, the neighboring passing voltage generator configured to increase the neighboring passing voltage for programming the selected memory cell.

Features and advantages consistent with the disclosure will be set forth in part in the description which follows, and in part will be obvious from the description, or may be learned by practice of the disclosure. Such features and advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIGS. 1(A) and 1(B) schematically show a programming process for programming a flash memory and a threshold voltage distribution after programming.

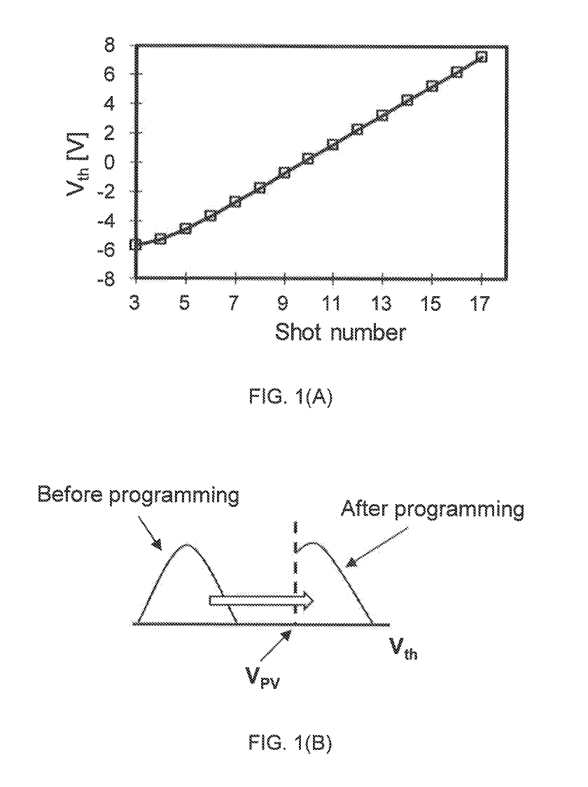

FIG. 2 schematically shows a memory cell array.

FIG. 3 schematically shows an exemplary timing plot for a programming voltage, a neighboring passing voltage, and a passing voltage.

FIG. 4 is a flow chart showing an exemplary method for programming a memory cell array.

FIG. 5 is a graph illustrating the increase of a threshold of a selected cell during a programming process.

FIG. 6 is a block diagram schematically showing an exemplary programming device for programming a memory cell array.

### DESCRIPTION OF THE EMBODIMENTS

Embodiments consistent with the disclosure include a device and a method for programming memory cells.

Hereinafter, embodiments consistent with the disclosure will be described with reference to drawings. Wherever possible, the same reference numbers will be used throughout the drawings to refer to the same or like parts.

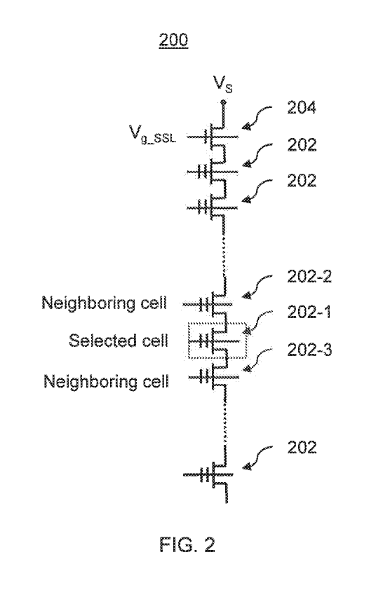

FIG. 2 schematically shows a memory cell array 200, which may be a NAND-type memory cell array. Memory cell array 200 includes a plurality of memory cells 202, which may be floating-gate MOS transistors. The memory cell array 200 further includes a control transistor 204, which may be a normal MOS transistor. During programming, a voltage V_{g}_{_{—}}_{SSL} is applied to the gate of control transistor 204 to turn on control transistor 204, so that a voltage source Vₛ is supplied to memory cell array 200. Consistent with embodiments of the present disclosure, when a cell 202-1 is to be programmed, a programming voltage V_{prog} is applied to the control gate of cell 202-1. Cell 202-1 may have two neighboring cells 202-2 and 202-3 directly coupled to cell 202-1. For example, one of the neighboring cells 202-2 and 202-3 may be connected to the source of cell 202-1, and the other one may be connected to the drain of cell 202-1. In some situations, when selected cell 202-1 is, for example, the first or the last cell in memory cell array 200, selected cell 202-1 may have only one neighboring cell connected to the source or the drain of cell 202-1. Consistent with embodiments of the present disclosure, a neighboring passing voltage Vₚₐₛₛ_{_{—}}ₙₑᵢ is applied to the control gate of each of the neighboring cells 202-2 and 202-3. In addition, a passing voltage Vₚₐₛₛ is applied to control gates of other memory cells 202 in memory cell array 200. The passing voltage Vₚₐₛₛ and the neighboring passing voltage Vₚₐₛₛ_{_{—}}ₙₑᵢ may be high enough to turn on corresponding memory cells to which they are applied. Therefore, current can flow through memory cell array 200, and selected cell 202-1 can be programmed.

Consistent with embodiments of the present disclosure, the voltages V_{prog}, Vₚₐₛₛ_{_{—}}ₙₑᵢ, and Vₚₐₛₛ may be each applied as pulses. For example, the width of each pulse may be about 10 μs.

Consistent with embodiments of the present disclosure, a programming process may include two stages. The passing voltage Vₚₐₛₛ may remain constant, while the programming voltage V_{prog} and the neighboring passing voltage Vₚₐₛₛ_{_{—}}ₙₑᵢ incrementally increase during the two stages, respectively. In the present disclosure, when a voltage is applied as pulses, the voltage being constant means each pulse of the voltage being about the same as a previous pulse of the voltage. On the other hand, a voltage (which is applied as pulses) incrementally increasing means each pulse of the voltage being higher than a previous pulse of the voltage. For example, in a first stage, the programming voltage V_{prog} may be an incrementally increasing voltage, i.e., each pulse of the programming voltage V_{prog} is higher than a previous pulse. On the other hand, the neighboring passing voltage Vₚₐₛₛ_{_{—}}ₙₑᵢ and the passing voltage Vₚₐₛₛ in the first stage may be kept constant, i.e., each pulse of the neighboring passing voltage Vₚₐₛₛ_{_{—}}ₙₑᵢ or the passing voltage Vₚₐₛₛ is about the same as a previous pulse. After each shot of pulses, the threshold voltage of selected cell 202-1 is measured. The first stage continues until the threshold voltage Vₜₕ of selected cell 202-1 (hereinafter, unless otherwise specified, the threshold voltage Vₜₕ refers to the threshold voltage of selected cell 202-1) becomes equal to or higher than a first programming verification voltage V_{PV1}, after which time a second stage begins. In the second stage, the programming voltage V_{prog} and the passing voltage Vₚₐₛₛ may be kept constant, i.e., each pulse of the programming voltage V_{prog} or the passing voltage Vₚₐₛₛ is about the same as a previous pulse. On the other hand, the neighboring passing voltage Vₚₐₛₛ_{_{—}}ₙₑᵢ in the second stage may be an incrementally increasing voltage, i.e., each pulse of the neighboring passing voltage Vₚₐₛₛ_{_{—}}ₙₑᵢ is higher than a previous pulse. The second stage continues until the threshold voltage Vₜₕ becomes equal to or higher than a second programming verification voltage V_{PV2}, which is higher than the first programming verification voltage V_{PV1}. The second programming verification voltage V_{PV2} may equal a desired programming verification voltage.

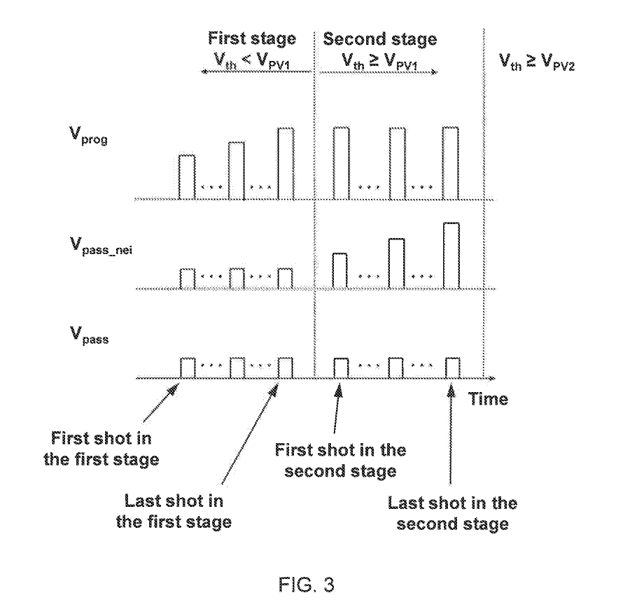

FIG. 3 schematically shows a timing plot for the programming voltage V_{prog}, the neighboring passing voltage Vₚₐₛₛ_{_{—}}ₙₑᵢ, and the passing voltage Vₚₐₛₛ consistent with embodiments of the present disclosure. In FIG. 3, in each of the first and second stages, only 3 pulses (first pulse, last pulse, and a pulse in between) of each of V_{prog}, Vₚₐₛₛ_{_{—}}ₙₑᵢ, and Vₚₐₛₛ are shown. This is exemplary. In each stage, there may be more or less than 3 pulses. As shown in FIG. 3, the passing voltage Vₚₐₛₛ is approximately constant during both stages of the programming process. In the first stage of the programming process, the neighboring passing voltage Vₚₐₛₛ_{_{—}}ₙₑᵢ is approximately constant, and may have the same value as the passing voltage Vₚₐₛₛ, and the programming voltage V_{prog} is incrementally increased. In the second stage, the programming voltage V_{prog} is kept at a constant value, such as the voltage level of the last pulse applied to selected cell 202-1 in the first stage. On the other hand, the neighboring passing voltage Vₚₐₛₛ_{_{—}}ₙₑᵢ is incrementally increased.

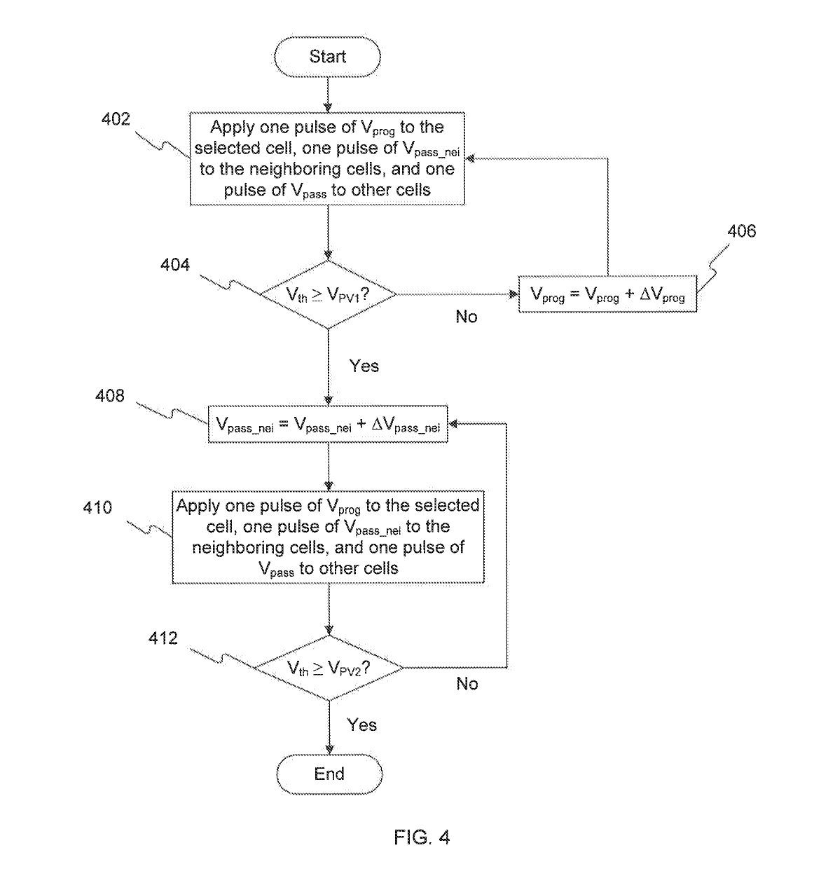

FIG. 4 is a flow chart showing a method for programming a memory cell array, such as memory cell array 200 shown in FIG. 2, consistent with embodiments of the present disclosure. The programming process starts with the first stage as described above in connection with FIG. 3. Specifically, at Step 402, one pulse of V_{prog} is applied to the control gate of selected cell 202-1, one pulse of Vₚₐₛₛ_{_{—}}ₙₑᵢ is applied to the control gates of the neighboring cells 202-2 and 202-3, and one pulse of Vₚₐₛₛ is applied to the control gates of other memory cells 202. At the first stage, Vₚₐₛₛ_{_{—}}ₙₑᵢ may be set to be the same as Vₚₐₛₛ (note that Vₚₐₛₛ may remain constant throughout the programming process), which may be, for example, about 8 volts. A first pulse of V_{prog} may be, for example, about 9 volts.

At Step 404, the threshold voltage Vₜₕ of selected cell 202-1 is measured and compared with the first programming verification voltage V_{PV1} to determine whether Vₜₕ equals to or is higher than V_{PV1}. The first programming verification voltage V_{PV1} may be, for example, about 0 V to about 1 V. If the determination result at Step 404 is no, the process proceeds to Step 406, when the programming voltage V_{prog} is increased by an incremental programming voltage ΔV_{prog}. The process then returns to Step 402 to perform another shot with the increased programming voltage V_{prog} but un-changed Vₚₐₛₛ_{_{—}}ₙₑᵢ and Vₚₐₛₛ In some embodiments, the incremental programming voltage ΔV_{prog} is about the same each time the programming voltage V_{prog} is increased at Step 406, and may be, for example, about 1 volt. In other embodiments, the incremental programming voltage ΔV_{prog} may not be the same each time the programming voltage V_{prog} is increased at Step 406.

On the other hand, if the determination result at Step 404 is yes, the process proceeds to Step 408, and the second stage of the programming process begins. At Step 408, the neighboring passing voltage Vₚₐₛₛ_{_{—}}ₙₑᵢ is increased by an incremental neighboring passing voltage ΔVₚₐₛₛ_{_{—}}ₙₑᵢ. In some embodiments, the incremental neighboring passing voltage ΔVₚₐₛₛ_{_{—}}ₙₑᵢ is about the same each time the neighboring passing voltage Vₚₐₛₛ_{_{—}}ₙₑᵢ is increased at Step 408, and may be, for example, about 1 volt. In other embodiments, the incremental programming voltage ΔVₚₐₛₛ_{_{—}}ₙₑᵢ may not be the same each time the neighboring passing voltage Vₚₐₛₛ_{_{—}}ₙₑᵢ is increased at Step 408. After the neighboring passing voltage Vₚₐₛₛ_{_{—}}ₙₑᵢ is increased, the process proceeds to Step 410, at which one pulse of V_{prog} is applied to the control gate of selected cell 202-1, one pulse of Vₚₐₛₛ_{_{—}}ₙₑᵢ is applied to the control gates of the neighboring cells 202-2 and 202-3, and one pulse of Vₚₐₛₛ is applied to the control gates of other memory cells 202. At this stage, the programming voltage V_{proq} may be kept constant and may be equal to the last pulse of programming voltage V_{prog} in the first stage.

At Step 412, the threshold voltage Vₜₕ of the selected cell 202-1 is measured and compared with the second programming verification voltage V_{PV2} to determine whether Vₜₕ equals to or is higher than V_{PV2}. The second programming verification voltage V_{PV2} may be, for example, about 1V to about 2V. If the determination result at Step 412 is no, the process returns to Step 408. On the other hand, if the determination result at Step 412 is yes, the process ends, i.e., the programming of selected cell 202-1 is finished.

In the embodiments described above, the neighboring passing voltage Vₚₐₛₛ_{_{—}}ₙₑᵢ is applied to both neighboring cells 202-2 and 202-3. However, the present disclosure is not so limited. For example, in some embodiments, the neighboring passing voltage Vₚₐₛₛ_{_{—}}ₙₑᵢ may be applied to one of the neighboring cells 202-2 and 202-3, and the other one of the neighboring cells 202-2 and 202-3 is applied with the passing voltage Vₚₐₛₛ that is applied to other cells. Of course, in the situation where selected cell 202-1 has only one neighboring cell, the neighboring passing voltage Vₚₐₛₛ_{_{—}}ₙₑᵢ would be applied to that only neighboring cell.

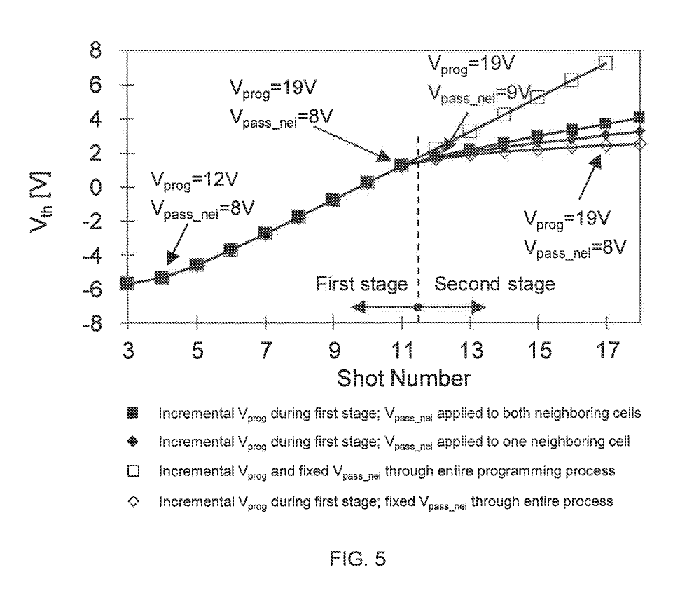

FIG. 5 is a graph showing simulation results of programming selected cell 202-1. In particular, FIG. 5 illustrates the increase of the threshold Vₜₕ of the selected cell 202-1 during various programming processes. The abscissa represents the shot number and the ordinate represents the threshold voltage Vₜₕ. The curve with solid square points and the curve with solid diamond points represent the results consistent with embodiments of the present disclosure. Specifically, the curve with solid square points shows the increase of Vₜₕ in a case where the incrementally increasing Vₚₐₛₛ_{_{—}}ₙₑᵢ is applied to both of the neighboring cells 202-2 and 202-3 in the second stage of the programming process. The curve with solid diamond points shows the increase of Vₜₕ in a case where the incrementally increasing Vₚₐₛₛ_{_{—}}ₙₑᵢ is applied to one of the neighboring cells 202-2 and 202-3 in the second stage of the programming process, while the fixed passing voltage Vₚₐₛₛ (which is also applied to other memory cells 202) is applied to the other one of the neighboring cells 202-2 and 202-3.

As a comparison, FIG. 5 also shows the results of a programming process with an incrementally increasing V_{prog} but a fixed Vₚₐₛₛ_{_{—}}ₙₑᵢ during the entire programming process (the curve with hollow square points), and the results of a programming process with an incrementally increasing V_{prog} and a fixed Vₚₐₛₛ_{_{—}}ₙₑᵢ in the first stage but a fixed V_{prog} and a fixed Vₚₐₛₛ_{_{—}}ₙₑᵢ in the second stage (the curve with hollow diamond points) of the programming process. Note that all the different programming processes are the same before the threshold voltage Vₜₕ reaches the first programming verification voltage Vpᵥₜ, which occurs after the 11th shot in FIG. 5. Therefore, as shown in FIG. 5, the portions of the four curves before shot number 11 overlap with each other.

It can be seen from FIG. 5 that, as compared to the programming process with an incrementally increasing V_{prog} but a fixed Vₚₐₛₛ_{_{—}}ₙₑᵢ during the entire programming process (hereinafter referred to as incremental step pulse (ISP) V_{prog} process, illustrated with the curve with hollow square points), the programming process using an incrementally increasing Vₚₐₛₛ_{_{—}}ₙₑᵢ applied to one or both of the neighboring cells 202-2 and 202-3 during the second stage (hereinafter referred to as one-side ISP Vₚₐₛₛ_{_{—}}ₙₑᵢ process and two-side ISP Vₚₐₛₛ_{_{—}}ₙₑᵢ process, respectively) results in slower increase in the threshold voltage Vₜₕ in the second stage. Therefore, the width of Vₜₕ distribution after the ISP Vₚₐₛₛ_{_{—}}ₙₑᵢ process is reduced as compared to the width of Vₜₕ distribution after the ISP V_{prog} process.

For example, under the conditions discussed above with respect to FIG. 5, after programming all the memory cells 202 using the ISP V_{prog} process, the difference between the threshold voltage Vₜₕ of a memory cell 202 having a highest threshold voltage and the threshold voltage Vₜₕ of a memory cell having a lowest threshold voltage (which approximately equals to V_{PV2}) is about 1 V (hereinafter, such a difference is referred to as a “width of the distribution of Vₜₕ”). On the other hand, the widths of the distributions of Vₜₕ after programming all the memory cells 202 using the one-side ISP Vₚₐₛₛ_{_{—}}ₙₑᵢ process and using the two-side ISP Vₚₐₛₛ_{_{—}}ₙₑᵢ process are about 0.37 V and about 0.23 V, respectively. That is, the distribution of Vₜₕ is narrower in the case where the ISP Vₚₐₛₛ_{_{—}}ₙₑᵢ process is performed, as compared to the distribution of Vₜₕ in the case where the ISP V_{prog} process (either one-side or two-side) is performed.

Referring again to FIG. 5, as compared to the programming process with a fixed V_{prog} and a fixed Vₚₐₛₛ_{_{—}}ₙₑᵢ in the second stage (hereinafter referred to as fixed-voltage process), the ISP Vₚₐₛₛ_{_{—}}ₙₑᵢ process has a steeper slope in the second stage. That is, the threshold voltage Vₜₕ in the ISP Vₚₐₛₛ_{_{—}}ₙₑᵢ process may reach the second programming verification voltage V_{PV2} relatively faster than that in the fixed-voltage process. Therefore, the ISP Vₚₐₛₛ_{_{—}}ₙₑᵢ process may require less time for programming as compared to the fixed-voltage process. On the other hand, the fixed-voltage process may require much longer time for the threshold voltage Vₜₕ to reach V_{PV2}, and may be practically not suitable.

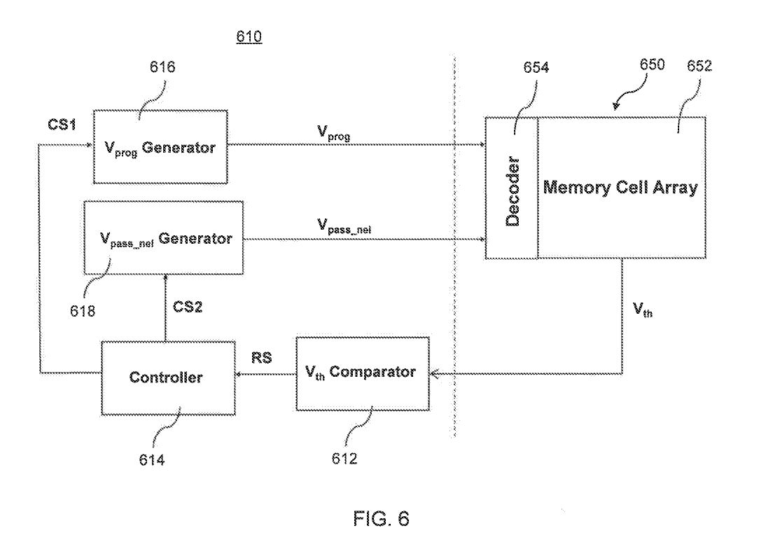

FIG. 6 is a block diagram schematically showing, on the left side of the figure, a programming device 610 consistent with embodiments of the present disclosure. Programming device 610 includes a threshold voltage Vₜₕ comparator 612, a controller 614, a programming voltage V_{prog} generator 616, and a neighboring passing voltage Vₚₐₛₛ_{_{—}}ₙₑᵢ generator 618. FIG. 6 also shows a memory device 650, which may be a NAND-type memory. Programming device 610 may be coupled to memory device 650 to program a memory cell array 652 in memory device 650. Memory cell array 652 may include one or more of memory cell array 200 shown in FIG. 2. As shown in FIG. 6, memory device 650 also includes a decoder 654, which may be used to decode memory addresses to apply the various voltages to corresponding memory cells.

Programming device 610 may operate according to a process consistent with embodiments of the present disclosure, such as, for example, one of the processes shown in FIG. 5. Specifically, Vₜₕ comparator 612 measures the threshold voltage Vₜₕ of a selected cell of the cell array 652 and compares it with the first programming verification voltage V_{PV1} or the second programming verification voltage V_{PV2} (depending on the stage of the programming process). The comparison result is sent, as a result signal (RS), to controller 614. Controller 614 generates two control signals CS1 and CS2 according to the result signal, and sends the control signals CS1 and CS2 to V_{prog} generator 616 and Vₚₐₛₛ_{_{—}}ₙₑᵢ generator 618, respectively. For example, if the RS signal indicates that the threshold voltage Vₜₕ is lower than the first programming verification voltage V_{PV1}, consistent with the embodiment illustrated in FIG. 3, control signal CS1 will instruct the programming voltage generator 616 to generate a pulse of V_{prog} higher than the previous pulse of V_{prog} by ΔV_{prog}, and control signal CS2 will instruct the neighboring passing voltage generator 618 to generate a pulse of Vₚₐₛₛ_{_{—}}ₙₑᵢ equal to the previous pulse of Vₚₐₛₛ_{_{—}}ₙₑᵢ. As another example, if the RS signal indicates that the threshold voltage Vₜₕ is equal to or is higher than the first programming verification voltage V_{PV1} but lower than the second programming verification voltage V_{PV2}, control signal CS1 will instruct V_{prog} generator 616 to generate a pulse of V_{prog} equaling the previous pulse of V_{prog}, and control signal CS2 will instruct Vₚₐₛₛ_{_{—}}ₙₑᵢ generator 618 to generate a pulse of Vₚₐₛₛ_{_{—}}ₙₑᵢ higher than the previous pulse of Vₚₐₛₛ_{_{—}}ₙₑᵢ by ΔVₚₐₛₛ_{_{—}}ₙₑᵢ. V_{prog} generator 616 and Vₚₐₛₛ_{_{—}}ₙₑᵢ generator 618 generate corresponding programming voltage V_{prog} and neighboring passing voltage Vₚₐₛₛ_{_{—}}ₙₑᵢ, respectively, according to control signals CS1 and CS2, and sends the generated voltages to decoder 654 to be applied to corresponding memory cells in memory cell array 652.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for programming memory cells comprising:
applying a programming voltage to a selected memory cell in a memory cell array and a neighboring passing voltage to a neighboring memory cell next to the selected memory cell;
increasing the programming voltage; and
increasing the neighboring passing voltage.

2. The method according to claim 1, wherein increasing the programming voltage includes increasing the programming voltage until a threshold voltage of the selected memory cell reaches a first programming verification voltage.

3. The method according to claim 1, wherein increasing the neighboring passing voltage comprises increasing the neighboring passing voltage after a threshold voltage of the selected memory cell reaches a first programming verification voltage.

4. The method according to claim 3, wherein increasing the neighboring passing voltage comprises increasing the neighboring passing voltage until the threshold voltage reaches a second programming verification voltage higher than the first programming verification voltage.

5. The method according to claim 1, further comprising,
applying a passing voltage to other memory cells in the memory cell array, the passing voltage remaining approximately the same during the programming of the memory cells.

6. The method according to claim 1, further comprising:
maintaining the neighboring passing voltage at approximately the same level while increasing the programming voltage.

7. The method according to claim 6, wherein maintaining the neighboring passing voltage at approximately the same level includes maintaining the neighboring passing voltage approximately the same as a passing voltage applied to other memory cells in the memory cell array, the passing voltage remaining approximately the same during the programming of the memory cells.

8. The method according to claim 1, further comprising:
maintaining the programming voltage at approximately the same level while increasing the neighboring passing voltage.

9. The method according to claim 8, wherein maintaining the programming voltage at approximately the same level includes maintaining the programming voltage approximately the same as a value of the programming voltage immediately before the threshold voltage reaches the first programming verification voltage.

10. The method according to claim 1, wherein the applying comprises applying the programming voltage and the neighboring passing voltage as pulses.

11. The method according to claim 10, wherein increasing the programming voltage comprises increasing the programming voltage pulse by pulse.

12. The method according to claim 10, wherein increasing the neighboring passing voltage comprises increasing the neighboring passing voltage pulse by pulse.

13. The method according to claim 1, wherein applying the neighboring passing voltage to the neighboring cell includes:
applying a voltage high enough to turn on the neighboring cell as the neighboring passing voltage.

14. The method according to claim 1, wherein the neighboring cell is a first one of two neighboring cells next to the selected cell, the method further comprising:
applying the neighboring passing voltage to a second one of the two neighboring memory cells.

15. A device for programming memory cells, comprising:
a programming voltage generator configured to generate a programming voltage to be applied to a selected memory cell in a memory cell array, the programming voltage generator configured to increase the programming voltage for programming the selected memory cell; and
a neighboring passing voltage generator configured to generate a neighboring passing voltage to be applied to a neighboring memory cell next to the selected memory cell, the neighboring passing voltage generator configured to increase the neighboring passing voltage for programming the selected memory cell.

16. The device according to claim 15, wherein the programming voltage generator is further configured to increase the programming voltage until a threshold voltage of the selected memory cell reaches a first programming verification voltage.

17. The device according to claim 15, wherein the neighboring passing voltage generator is further configured to increase the neighboring passing voltage until a threshold voltage of the selected memory cell reaches a second programming verification voltage.

18. The device according to claim 15, wherein the neighboring passing voltage generator is further configured to maintain the neighboring passing voltage at approximately the same level while the programming voltage generator increases the programming voltage.

19. The device according to claim 15, wherein the programming voltage generator is further configured to maintain the programming voltage at approximately the same level while the neighboring passing voltage generator increases the neighboring passing voltage.

20. The device according to claim 15,
wherein the programming voltage generator is further configured to generate the programming voltage as pulses, and
wherein the neighboring passing voltage generator is further configured to generate the neighboring passing voltage as pulses.

21. The device according to claim 15, further comprising:
a threshold voltage comparator configured to compare a threshold voltage of the selected memory cell with a first programming verification voltage or a second programming verification voltage and output a comparison result; and
a controller configured to generate a first control signal and a second control signal according to the comparison result,
wherein the programming voltage generator is configured to generate the programming voltage according to the first control signal, and
wherein the neighboring passing voltage generator is configured to generate the neighboring passing voltage according to the second control signal.
